(19) United States
(12) Patent Application Publication
(10) Pub. No.: US 2004/0126492 A1
(43) Pub. Date: Jul. 1, 2004

(54) Method and apparatus for using ion plasma deposition to produce coating

(76) Inventors: Scott Andrew Weaver, Ballston Lake, NY (US); Reed Roeder Corderman, Niskayuna, NY (US); Don Mark Lipkin, Niskayuna, NY (US); Ronald Dennis Rodrigue, Pattersonville, NY (US)

Correspondence Address: GENERAL ELECTRIC COMPANY, GLOBAL RESEARCH, PATENT DOCKET RM. BLDG. K1-4A59, SCHENECTADY, NY, 12301-0008, US

(21) Appl. No.: 10/331,578

(22) Filed: Dec. 30, 2002

(51) Int. Cl. C23C 16/00; H05H 1/00; H05H 1/24

(52) U.S. Cl. 427/250; 427/569; 118/715

(57) ABSTRACT

A method of depositing a coating at a substrate via ion plasma deposition comprises subjecting a cathode and the substrate to a vacuum environment, applying a bias voltage to the substrate, supplying a current to the cathode, operating a cathodic arc from the cathode, and depositing an alloy coating from the cathode at a surface of the substrate. The cathode comprises a nickel-aluminum family alloy. The coating deposited is a nickel-aluminum family alloy. A cathode for an ion plasma deposition process comprises a body fabricated from a first composition, and a plug disposed at the body, the plug being fabricated from a second composition. A nickel-aluminum family cathode having a tapered outer surface comprises a body tapered along a longitudinal axis thereof and a ring having a tapered inner surface at which the tapered outer surface of the body is received.

### BACKGROUND OF THE INVENTION

This disclosure relates generally to ion plasma deposition and, more particularly, to a method of using ion plasma deposition to produce nickel-aluminum (Ni—Al) family environmental and bond coatings and to provide surface restoration. The disclosure also particularly relates to a cathode for producing the nickel-aluminum family coatings.

Environmental and bond coatings generally comprise either diffusion coatings or overlay coatings. Diffusion coatings typically include simple or platinum-modified aluminide coatings, the latter being most often applied by electroplating a thin layer of platinum onto a surface and aluminizing the surface using a vapor-phase or pack process. Overlay coatings typically include MCrAlY alloys where M can be one or more of nickel, cobalt, and iron and are most often applied by either thermally spraying a powder or by physical vapor deposition techniques (e.g., electron beam evaporation). Both diffusion and overlay coatings are oftentimes utilized in the high temperature applications associated with gas turbine operation, and particularly at the surfaces of airfoils disposed within the high temperature gas path of turbine engines. Because such coatings are subject to extreme oxidizing and hot corrosive environments in the high temperature gas path of the turbine, they are subject to degradation and oftentimes require replacement on a regular basis, e.g., by reapplication of the coatings via convenient methods.

In addition to the loss of the surface coatings of the airfoils in the high temperature environment, surfaces of the tips of the blade are subject to oxidation and abrasive wear as a result of physical contact with the turbine shroud during operation. Oxidation or wear of the tip surface beyond a certain point causes both the exhaust gas temperature and the specific fuel consumption of the turbine to increase beyond acceptable levels. The blades must then be removed from the turbine and restored to their original dimensions by adding alloy material to the tip surface. Refinishing of the blade tip, particularly replacement of abrasively-removed substrate material, is generally effected by weld restoration of alloy at the tip, followed by restoration of the diffusion or overlay coating as described above.

It is therefore generally desirable to provide coatings on turbine components, particularly the surfaces of the airfoils, that provide superior oxidation and hot corrosion protection to the component surfaces. In general, it is desirable to provide a high temperature oxidation/corrosion resistant coating that is easily depositable on the surfaces of a turbine airfoil in order to increase the temperature capability and the effective life of the airfoil. Further, it is desirable to provide a restored blade tip that provides oxidation resistance to the blade surface.

### BRIEF DESCRIPTION OF THE INVENTION

Disclosed herein is a method of depositing a coating at a substrate via ion plasma deposition. The method comprises subjecting a cathode and the substrate to a vacuum environment, applying a bias voltage to the substrate, supplying a current to the cathode, operating a cathodic arc from the cathode, and depositing alloy coating from the cathode at a surface of the substrate. The cathode comprises a nickel-aluminum family alloy. The coating deposited is a nickel-aluminum family alloy. A nickel-aluminum alloy cathode for an ion plasma deposition process comprises a body fabricated from a first composition, and a plug (optional) disposed at the body, the plug being fabricated from a second composition. A nickel-aluminum alloy cathode having a tapered outer surface comprises a body tapered along a longitudinal axis thereof and a ring comprising a tapered inner surface at with the tapered outer surface of the body is received.

Further aspects of the method and apparatus are disclosed herein. The above-discussed and other features and advantages of the present invention will be appreciated and understood by those skilled in the art from the following detailed description and drawings.

### BRIEF DESCRIPTION OF THE DRAWINGS

Referring now to the Figures, which depict exemplary embodiments, and wherein like elements are numbered alike:

FIG. 1 is a schematic representation of an ion plasma deposition apparatus;

FIG. 2 is a cross-sectional view of a cathode assembly of the ion plasma deposition apparatus;

FIG. 3 is a cross-sectional view of a cathode;

FIG. 4 is a cross-sectional view of a cathode retained in a mounting cradle;

FIG. 5 is a cross-sectional view of a tapered cathode retained in a mounting cradle;

FIG. 6 is a schematic representation of an airfoil tip having a release agent deposited on a surface thereof prior to deposition of an ion plasma coating; and

FIG. 7 is a graphical representation of the effect of substrate bias on coating deposition rate and substrate temperature for an ion deposition process.

### DETAILED DESCRIPTION OF THE INVENTION

Disclosed herein is a method of using ion plasma deposition to apply alloy coatings, particularly Ni—Al family coatings, to components for use in extreme environments. The Ni—Al coatings may be environmental coatings (e.g., coatings that protect a surface from environmental elements) or bond coatings (e.g., coatings that effect the adherence of the substrate to a superlayer coating such as a thermal barrier coating). Extreme environments into which the coatings may be incorporated include the oxidizing and hot corrosive environments associated with the operation of high-pressure, high-temperature gas turbines. Although the embodiments below are described with reference to Ni—Al coatings, it should be understood that the exemplary embodiments of the method described below may be utilized to apply other coatings. Nickel-aluminum family coatings are generally alloys comprising both nickel and aluminum. Nickel-aluminum family coatings that may be applied include, but are not limited to, those in the beta-NiAl sub-family, the MCrAlY sub-family, and those in the gamma-gamma prime sub-family.

Ion plasma deposition is a high-rate physical vapor deposition (PVD) process in which an electric vacuum arc vaporizes a cathode surface. After ignition at the surface of the cathode, the arc is sustained by the supply of electrical current through the cathode. The arc produces a plasma of highly ionized vapor and, because of the high energy of the arc process, all of the alloying elements of the cathode are uniformly ablated, thereby providing a chemistry transfer to the substrate. Coatings derived from multi-component metallic Ni—Al family cathodes may be deposited onto turbine airfoils to impart high-temperature oxidation/corrosion resistance as well as to provide adhesion of oxide thermal barrier coatings (TBC) to the airfoil surfaces. To limit undesirable differential sputtering at the substrate and to maintain high deposition rates, a relatively low negative voltage, or a substrate bias, is applied to the airfoil.

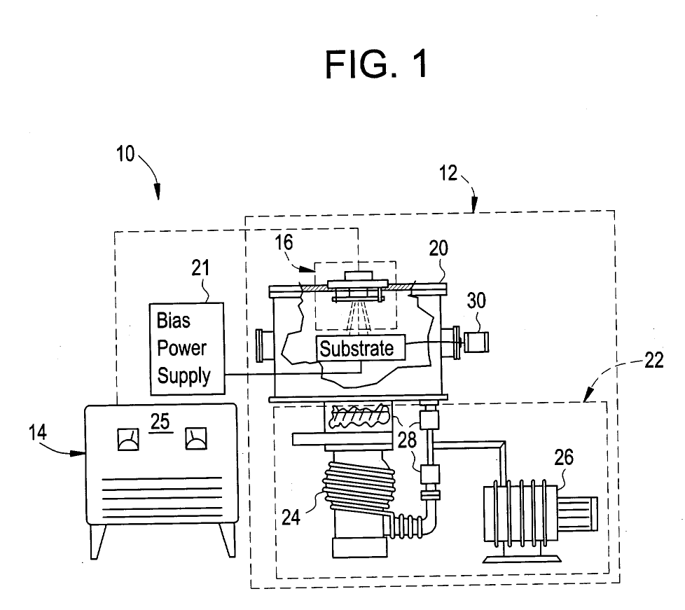

Referring now to FIG. 1, an ion plasma deposition apparatus is shown at 10 and is hereinafter referred to as “apparatus 10.” Apparatus 10 comprises a vacuum assembly system 12, at least one power supply system 14, and a corresponding number of cathode assembly systems 16. Vacuum assembly system 12 comprises an enclosed chamber 20 and a staged pump system 22 for evacuating enclosed chamber 20. Staged pump system 22 comprises a diffusion pump 24 and a mechanical rough pump 26. Valves 28 regulate fluid communication between enclosed chamber 20 and diffusion pump 24 in response to partial pressures sensed within vacuum assembly system 12 and allow enclosed chamber 20 to be isolated from diffusion pump 24 and evacuated prior to diffusion pump 24 being engaged. Additionally, a process gas supply (not shown) may be utilized to partially backfill enclosed chamber 20 with an inert or selectively reactive gas.

Prior to evacuation of enclosed chamber 20, a substrate (e.g., a turbine airfoil) is positioned within enclosed chamber 20 in preparation for coating. The substrate is preferably mounted on a sample manipulator within enclosed chamber 20. A bias power supply system 21 allows for the application of a variable bias voltage across the substrate. Application of the bias voltage increases the kinetic energy of the incident ions, which in turn allows for heating the substrate and promotes a more dense and adherent coating. To further increase coating uniformity, the sample manipulator/substrate assembly may be rotated by a motor drive 30, e.g., a planetary drive. The substrate bias voltage may also be employed for ion sputter cleaning of the substrate prior to coating deposition.

Once the substrate is mounted and enclosed chamber 20 is evacuated, power is supplied to cathode assembly system 16 and the arc is ignited. Power is derived from power supply system 14, which is preferably a direct current (DC) power supply 25 that includes a restart circuit and which is capable of producing at least about 50 amps at about 20 volts for a total power output of at least about 1,000 watts at a 100% duty cycle.

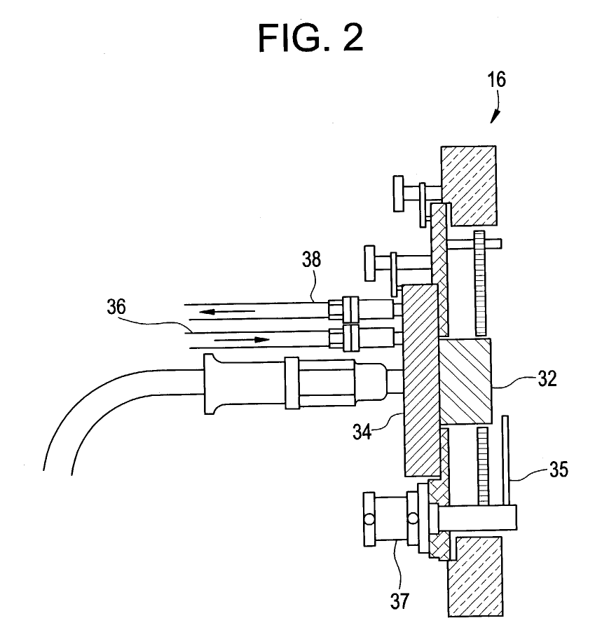

Referring now to FIG. 2, cathode assembly system 16 is shown. Cathode assembly system 16 is disposed at an interior wall of the enclosed chamber and comprises a cathode 32, which may be a composite structure or a homogenous structure, disposed at an evaporator plate 34. Cathode 32 is typically screwed, clamped, brazed, soldered, or similarly disposed at evaporator plate 34 and provides the source of material for the ion plasma deposition. A trigger wire 35 may be disposed in electrical communication with the power supply through a trigger assembly 37. When trigger assembly 37 is actuated, an arc is generated between trigger wire 35 and cathode 32. Once the arc is triggered, the vacuum arc is sustained by the current power supply and the material of cathode 32 is consumed, leading to vapor deposition onto the substrate. Because of the high power dissipation effected during the operation of the ion plasma deposition apparatus, evaporator plate 34 and the enclosed chamber are preferably fluid-cooled by, for example, circulating a fluid via a fluid inlet 36 and a fluid return 38. Exemplary fluids that may be utilized include, but are not limited to, water, oils, refrigerants, and the like.

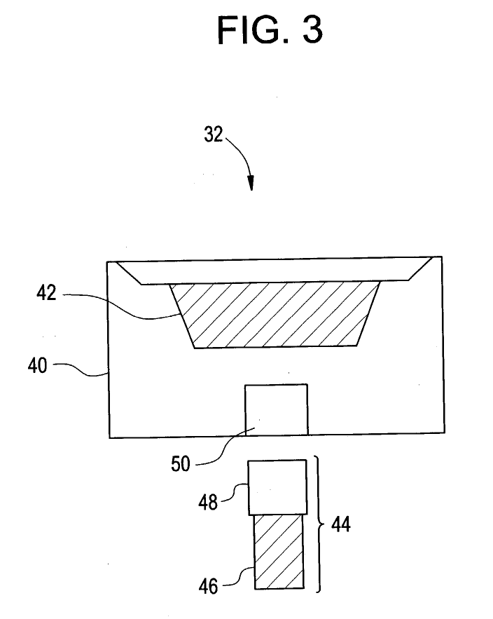

Cathode 32 provides the source of material for the ion plasma deposition. Cathode 32, as shown with reference to FIG. 3, may comprise a cast or powder metallurgical structure having a composition that corresponds to the desired coating composition. In particular, cathode 32 may be homogenous in composition or fabricated as a composite structure comprising a plurality of components that individually comprise homogenous compositions. In either case, the structure of cathode 32 preferably comprises a body 40 and at least one optional plug 42 disposed at body 40. Body 40 is fabricated from an alloy or a pure metal. Plug 42 is fabricated from a different alloy or pure metal and is inserted into body 40 to produce a cathode comprising at least two metal or alloy components. For example, in a Ni—Al family cathode, the average composition of the body and the plug corresponds to the composition of the desired coating. Cathode 32 is disposed within the cathode assembly system. Cathode 32 may be disposed within the cathode assembly system via a threaded screw, a clamp, a braze, or a solder attachment. Alternately, cathode 32 may be disposed within the cathode assembly system using a stud 44, which comprises a mounting end 46 and a fitting end 48. Mounting end 46 may be threaded, as shown, for mounting cathode 32 into the cathode assembly system. Fitting end 48 preferably forms an interference fit or is brazed at a receptacle 50 to body 40 to retain cathode 32 in the cathode assembly system.

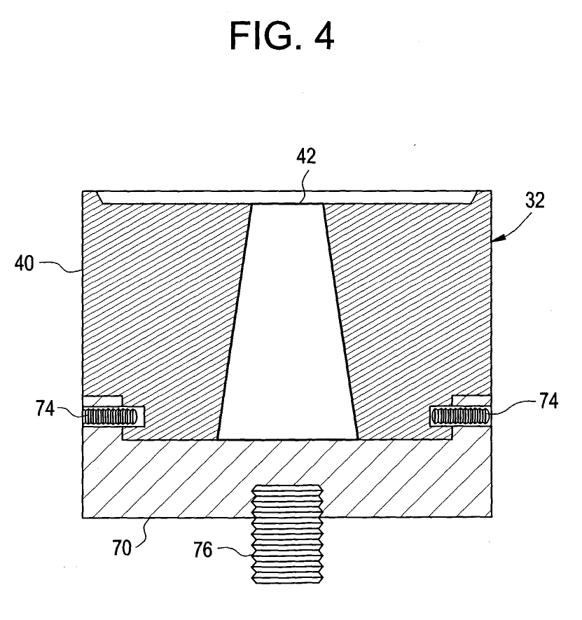

For a body/plug configuration of cathode 32, body 40 comprising a nominal composition of alloy or metal is cored out substantially at the center thereof. The cored out portion forms a hole that may or may not extend completely through body 40. The sides of the hole are preferably tapered such that a cross-section of the hole is larger at the outer surface of body 40 and smaller at an interior portion of body 40. Plug 42 is inserted into the hole and retained therein by the tapered sides in an interference fit. Alternately, plug 42 may be loosely inserted into the hole and body 40 may be shrink-fitted to retain plug 42 with or without the sides of the hole being tapered. Alternately, cathode 32 comprising body 40 (and optional plug 42) may be retained in a cradle 70 with set screws 74, as is shown in FIG. 4. Any number of set screws 74 may be used to retain body 40 at cradle 70. Set screws 74, as shown, may extend laterally through a lip disposed at cradle 70 in which body 40 is mounted. Set screws 74 may further engage holes or a groove disposed in a shoulder portion of body 40 to retain body 40 at cradle 70. Cradle 70 is preferably mounted within the cathode assembly system with a threaded stud 76, as is shown in FIG. 4, but may also be clamped, soldered, or brazed.

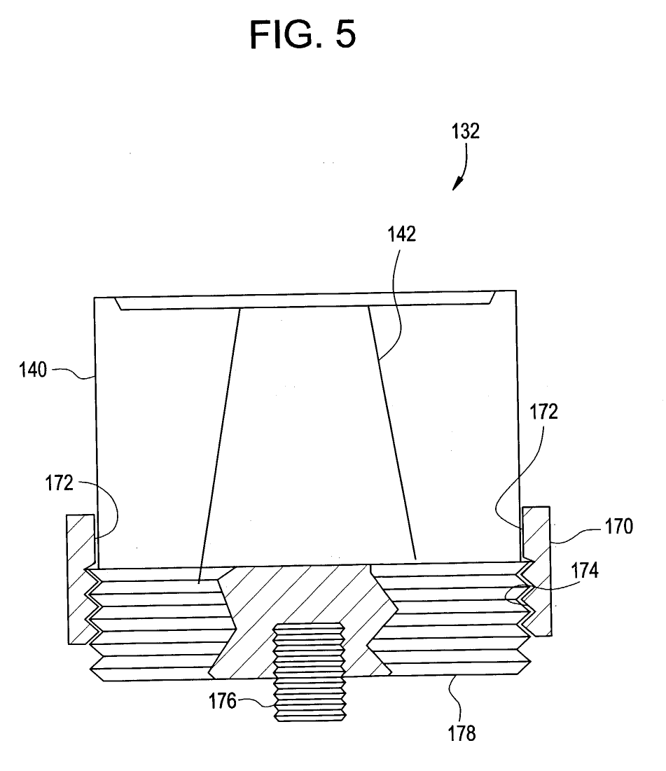

One exemplary embodiment of a nickel-aluminum family alloy cathode is shown at 132 with reference to FIG. 5. Cathode 132 comprises a tapered ring 170 configured to allow a body 140 fabricated from the desired cathode material to be inserted through the larger side and retained at the smaller side. Body 140 is preferably tapered at an outer surface and along a longitudinal axis thereof. Cathode 132 may further comprise a plug 142 fabricated from a material having a distinct composition from the body and which may or may not be tapered. The plug is inserted into body 140 in order to produce a composite cathode comprising at least two distinct components. The average composition of cathode 132 is adjusted to produce the desired nickel-aluminum family coating. The tapered ring/body configuration provides a means for retaining tapered body 140 without the use of set screws and machining of a shoulder surface. The smaller inner side of tapered ring 170 comprises a surface 172 that may be knurled or smooth such that an outer surface of tapered body 140 is securely retained in tapered ring 170. The larger inner side of tapered ring 170 comprises a thread 174. The threading of a base 178 into thread 174 enables tapered body 140 to be biased against surface 172 and securely retained within the ring. Base 178 is preferably retained in a cathode assembly system with a threaded stud 176, as is shown with reference to FIG. 5, but may alternately be clamped, soldered, or brazed.

In one exemplary embodiment of applying a coating to an airfoil using the ion plasma deposition apparatus, the enclosed chamber is first evacuated by the vacuum assembly system to establish a vacuum of about 10⁻⁴ torr to about 10⁻⁶ torr. After evacuation of the vacuum enclosure, a high negative bias voltage is applied to the airfoil. During the initial stages of the deposition process, the bias voltage is used to cause a positive ion bombardment of the airfoil surface, which provides for the simultaneous sputter cleaning (e.g., removal of adsorbed gases, oils, and dirt) and heating of the airfoil surface. The voltage to which the airfoil is biased is about −150 volts DC to about −1,000 volts DC and preferably about −300 volts DC to about −500 volts DC with respect to ground. The bias voltage is maintained during about the first 1 to 15 minutes of the coating process and preferably for about the first 5 to 10 minutes of the coating process. Subsequently, the bias voltage is reduced for the remainder of the deposition process.

To apply a multi-element coating from at least one multi-element cathode to the airfoil surface, a cathodic arc is operated at a power of about 1 kilowatt (kW) to about 3 kW, corresponding to a voltage of about 20 volts DC at amperages of about 50 amps (A) to about 150 A and preferably from about 75 A to about 100 A. A valve (e.g., a pneumatic valve) disposed at the trigger assembly is actuated to cause the trigger wire to contact the cathode surface, thereby causing arc ignition. Once the arc is established, a control mechanism monitors the apparatus to ensure the presence of the arc. If the arc is extinguished, the control mechanism re-triggers the arc. As stated above, after about 1 to 15 minutes and preferably about 5 to 10 minutes of the coating process, the bias voltage is reduced. By maintaining a low voltage across the substrate during deposition, a high rate of deposition can be maintained while minimizing the chemistry changes between the cathode and the coating. In another exemplary embodiment of a method for applying a multi-element coating, two or more cathodes, each comprising a subset of the desired coating chemistry, may be simultaneously utilized.

Another exemplary embodiment of a method for applying various alloy coatings to an airfoil surface comprises utilizing the ion plasma deposition technique to deposit alloy material at the tips of high pressure turbine (HPT) blades, such that the length of the blade and the appropriate geometry of the blade tip are restored. The HPT blade is preferably mounted and maintained in position via support tooling that closely approximates the outer contour of the HPT blade surface. In such a process, the HPT blade tip is positioned about 1 centimeter (cm) to about 15 cm away from the cathode of the ion plasma deposition apparatus, and preferably about 5 cm to about 10 cm.

Upon mounting the HPT blade, a negative bias voltage is applied to the blade to heat and to sputter clean the blade surface prior to deposition, thus promoting a strong metallurgical bond between the deposited alloy and the blade base metal, as well as maximizing the density of the deposit. In yet another exemplary embodiment of the method, the blade tip may be heated via radiation from quartz-halogen lamps positioned in close proximity to the blade tip. Such lamps are commercially available and are typically rated at about 500 W to about 1,000 W.

The alloy coating is applied to the HPT blade in the ion plasma deposition process as described above. In particular, the arc is ignited on the cathode and the alloy is deposited from the cathode onto the blade tip to the thickness required to restore the blade tip to its original dimensions. Alternately, excess alloy may be deposited onto the blade tip and subsequently machined off to restore the blade to its original dimensions.

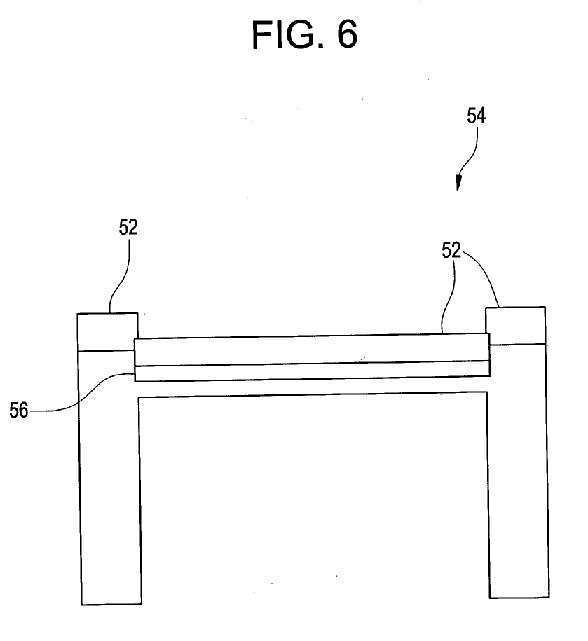

To prevent the undesirable buildup of an alloy coating 52 on an HPT blade 54 at surfaces that are not in need of restoration, a release agent 56 (e.g., calcium fluoride) may be applied to surfaces of blade 54 (e.g., the cap or plenum surfaces) prior to the deposition of alloy coating 52 on blade 54, as is shown in FIG. 6. Application of release agent 56 preferably inhibits the deposition of alloy material thereover by preventing a metallurgical bond with the blade surface. By preventing the formation of a metallurgical bond with the blade surface, inner contour machining of the tip after the alloy deposition may be simplified or even obviated.

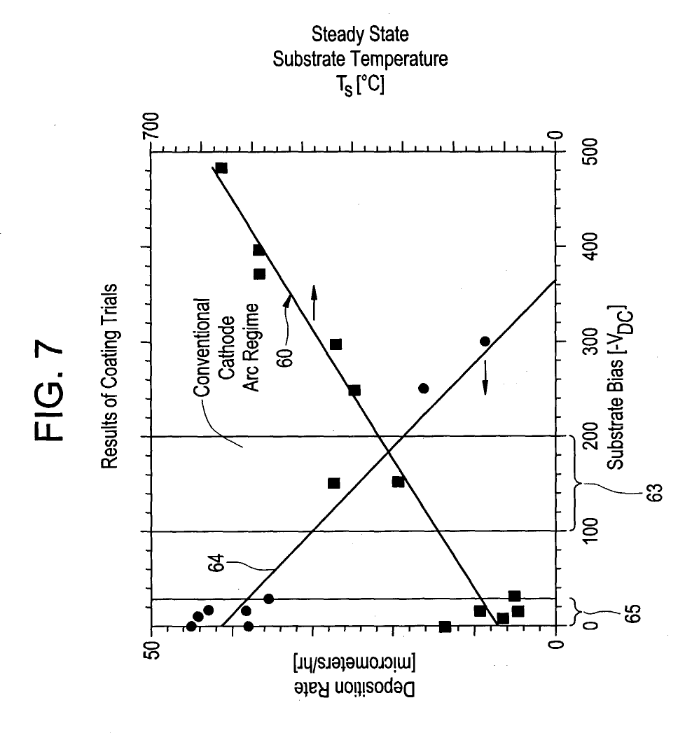

Referring now to FIG. 7, an illustration of deposition rate and substrate temperature are each shown as functions of the substrate bias. Line 60 represents the steady state substrate temperature. In the ion plasma deposition technique in which multi-component alloys, such as Ni—Al family alloys, are deposited utilizing the apparatus as described above, a substrate bias less than about 50 volts DC (as illustrated at a region 65) and preferably less than about 25 volts DC is used. In this deposition regime, multi-component alloys, such as Ni—Al alloys, are deposited at a high deposition rate while minimizing differential sputtering effects that lead to less than optimum chemistry transfers, thereby yielding a superior quality coating. Maintaining a high deposition rate keeps the substrate temperature and the coating density sufficiently high to assure high-quality deposit.

### EXAMPLE

Experiments were performed with the ion plasma deposition apparatus as described above. The Ni—Al family coatings used in the experiments contained about 18 weight percent (w/o) to about 26 w/o aluminum, about 6 w/o to about 12 w/o chromium, and about 0.5 w/o to about 1.5 w/o zirconium at a thickness of about 50 micrometers (um) and at substrate-to-cathode distances of about 10 centimeters (cm) to about 15 cm. Deposition times were about 1 hour for substrates fixed in position in the chamber and about 3 hours for substrates rotated about a single axis. Deposition rates for each substrate were about 0.8 um/min and about 0.3 um/min, respectively. In each trial, the cathodic arc was operated at about 80 A to about 100 A, and the arc potential was about 20 volts DC. During the first five minutes of each run, the substrates were biased to about −300 volts DC, the substrates reaching temperatures of about 500° C. to about 600° C. During the remainder of each run, the substrate bias was maintained at −5 volts DC to about −15 volts DC, and the temperatures remained at about 300° C. to about 400° C.

The above-described methods for the ion plasma deposition of Ni—Al family alloys on airfoil components have several advantages over other methods of applying coatings. First, as the coating process is effected in an evacuated chamber, no oxygen is present, and no combustion or crucible materials that may contaminate the coating are present. Thus, the ion deposition process results in high-purity coatings.

Second, the ion plasma deposition of multi-element metallic coatings onto airfoil components imparts superior bond coat performance (e.g., improved bond coating properties due to high temperature oxidation/hot corrosion resistance, thermal barrier coating and bond coat adherence, coating density, and the like) not heretofore effected on airfoil components by electroplated platinum-modified aluminide coatings or by thermally sprayed MCrAlY coatings. In thermocyclic tests in which samples having multi-component metallic coatings deposited by an ion plasma process are maintained at about 1,160° C. for 45 minutes and subsequently exposed to forced air cooling at ambient temperature, it has been noted that effective lifetimes of two to three times the lifetimes of standard platinum-modified aluminide coatings have been obtained. The ion plasma coated samples have also been noted to have equivalent or better high temperature environmental performance compared to samples having either electroplated platinum-modified coatings or thermally sprayed MCrAlY coatings.

Third, cathodes fabricated of multiple-element components enable multi-element coatings to be deposited onto the airfoil components with the use of either a single cathode or an arrangement of multiple cathodes. By incorporating various materials into one or more cathodes to produce the desired alloy coating, an ion plasma deposition apparatus with fewer sources (e.g., only one cathode instead of two or more) may be utilized to produce the coatings.

While the invention has been described with reference to various exemplary embodiments, it will be understood by those skilled in the art that various changes may be made and equivalents may be substituted for elements thereof without departing from the scope of the invention. In addition, modifications may be made to adapt a particular situation or material to the teachings of the disclosure without departing from the essential scope of the invention. Therefore, it is intended that the invention not be limited to the particular embodiments disclosed as the best mode contemplated for carrying out this invention, but that the invention will include all embodiments falling within the scope of the appended claims.

1. A method of depositing a coating at a substrate via ion plasma deposition, said method comprising:
subjecting a cathode and said substrate to a vacuum environment, said cathode comprising a nickel-aluminum family alloy;
applying a bias voltage to said substrate;
supplying a current to said cathode;
operating a cathodic arc from said cathode; and
depositing said nickel-aluminum family alloy from said cathode at a surface of said substrate.

2. The method of claim 1, wherein said bias voltage is reduced during said operating of said cathodic arc.

3. A method of applying an alloy coating to an airfoil surface in an ion plasma deposition process, said method comprising:
subjecting a first cathode and said airfoil surface to a vacuum environment;
applying a bias voltage to said airfoil surface;
applying a first current to said first cathode;
establishing an arc on said first cathode; and
depositing cathode material from said arc at said airfoil surface.

4. The method of claim 3, wherein said vacuum environment is maintained at about 10⁻⁴ torr to about 10⁻⁶ torr.

5. The method of claim 3, further comprising heating said airfoil surface.

6. The method of claim 5, wherein said heating is effected to a temperature of about 250° C. to about 1,200° C.

7. The method of claim 3, wherein said bias voltage is about −150 volts DC to about −1,000 volts DC.

8. The method of claim 7, further comprising reducing said bias voltage after about 1 minute to about 15 minutes of said applying of said first current.

9. The method of claim 7, further comprising reducing said bias voltage after about 5 minutes of said applying of said first current.

10. The method of claim 8, wherein said bias voltage is reduced to about 0 to about −50 volts DC. [preferred 0 to −20V DC]

11. The method of claim 8, wherein said bias voltage is reduced to about 0 to about −20 volts DC.

12. The method of claim 3, wherein said applying of said first current comprises applying an arc power to said first cathode at about 1 kW to about 3 kW.

13. The method of claim 3, wherein said applying of said first current comprises applying an arc power to said first cathode at about 1.5 kW to about 2 kW.

14. The method of claim 3, wherein said first cathode comprises a nickel-aluminum family alloy.

15. The method of claim 14, wherein said nickel-aluminum family alloy comprises a beta-NiAl sub-family.

16. The method of claim 14, wherein said nickel-aluminum family alloy comprises a MCrAlY sub-family or a gamma-gamma prime sub-family.

17. The method of claim 3, further comprising applying a second current to a second cathode, said second cathode comprising a composition different from said first cathode.

18. The method of claim 3, wherein said airfoil surface comprises a tip of a high pressure turbine blade.

19. The method of claim 18, further comprising applying a release agent at said airfoil surface.

20. A nickel-aluminum family cathode for an ion plasma deposition process, said cathode comprising:
a body fabricated from a first composition; and
a plug disposed at said body, said plug being fabricated from a second composition.

21. The cathode of claim 20, wherein said body comprises a hole into which said plug is disposed, said hole having a side wall that is tapered such that a cross-section of said hole is larger at an outer surface of said body and smaller at an interior portion of said body.

22. The cathode of claim 20, wherein said plug is inserted into a hole in said body and said body is shrink-fitted to retain said plug.

23. The cathode of claim 20, further comprising a mounting cradle disposed at said body.

24. The cathode of claim 23, further comprising a screw disposed at said mounting cradle, said screw being received in said body to retain said body at said cradle.

25. A nickel-aluminum family alloy cathode having a tapered outer surface, said cathode comprising:
a body fabricated from a first composition, said body having an outer surface that is tapered along a longitudinal axis of said body; and
a ring having a tapered inner surface at which said tapered outer surface of said body is received.

26. The cathode of claim 25, wherein said ring comprises a base threadedly received at a larger side of said ring, said base being configured to bias said tapered outer surface of said body against an inner surface at a smaller side of said ring.

27. The cathode of claim 25, further comprising a plug disposed at said body, said plug being fabricated from a second composition.
